(19) United States
(12) Patent Application Publication
(10) Pub. No.: US 2025/0221285 A1
(43) Pub. Date: Jul. 3, 2025

(54) Display Apparatus

(71) Applicant: LG Display Co., Ltd., Seoul (KR)

(72) Inventors: KwangHyun Baek, Paju-si (KR); Hyunjik Bae, Paju-si (KR)

(21) Appl. No.: 18/920,404

(22) Filed: Oct. 18, 2024

(30) Foreign Application Priority Data
Dec. 29, 2023 (KR) 10-2023-0196876

(51) Int. Cl. H10K 59/80; H10K 59/122; H10K 59/40; H10K 102/00

(52) U.S. Cl. CPC H10K 59/8792; H10K 59/122; H10K 59/40; H10K 59/879; H10K 2102/351

(57) ABSTRACT

Disclosed is a display apparatus comprising a substrate including a first emitting area and a second emitting area, a first insulating layer disposed on the substrate and including a first opening corresponding to the first light emitting area and a second opening corresponding to the second light emitting area, a first light control element disposed in the first opening, a second light control element disposed in the second opening, and a black matrix disposed on the first insulating layer in a region between the first emitting area and the second emitting area, wherein the first insulating layer includes a first side surface in contact with the first opening and an upper surface connected to the first side surface, and the black matrix is disposed on the first side surface and the upper surface of the first insulating layer.

### CROSS-REFERENCE TO RELATED APPLICATION

This application claims the benefit of the Republic of Korea Patent Application No. 10-2023-0196876 filed on Dec. 29, 2023, which is hereby incorporated by reference in its entirety.

### BACKGROUND

### Technical Field

The present disclosure relates to a display apparatus capable of controlling a viewing angle.

### Description of the Related Art

Electronic devices in various fields include display apparatus that display images. For example, a display apparatus for providing desired information or content to a driver and a passenger may be applied to a vehicle.

Among the display apparatus mounted on a vehicle, a display apparatus disposed at the center of the dashboard is in the process of being enlarged. This display apparatus needs to selectively provide information or content to a driver and/or a passenger according to a driving situation of a vehicle.

### SUMMARY

The present disclosure has been made in view of the above problems, and it is an object of the present disclosure to provide a display apparatus capable of effectively preventing or at least reducing light leakage and preventing a driver from obstructing driving.

In accordance with an aspect of the present disclosure, the above and other objects can be accomplished by the provision of a display apparatus comprising a substrate including a first emitting area and a second emitting area, a first insulating layer disposed on the substrate and including a first opening corresponding to the first light emitting area and a second opening corresponding to the second light emitting area, a first light control element disposed in the first opening, a second light control element disposed in the second opening, and a black matrix disposed on the first insulating layer in a region between the first emitting area and the second emitting area, wherein the first insulating layer includes a first side surface in contact with the first opening and an upper surface connected to the first side surface, and the black matrix is disposed on the first side surface and the upper surface of the first insulating layer.

Furthermore, the above and other objects can be accomplished by the provision of a display apparatus comprising a plurality of light emitting elements including a first light emitting element and a second light emitting element, a first light control element disposed in the first light emitting element, a second light control element disposed in the second light emitting element, and a black matrix disposed between the first light emitting element and the second light emitting element, wherein the black matrix is disposed between the first light control element and the second light control element, and the black matrix includes a first portion facing the first light control element and a second portion facing the second light control element.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a diagram schematically illustrating a configuration of a display apparatus according to an embodiment.

FIG. 2 is a cross-sectional view schematically illustrating a structure of a display panel according to an embodiment.

FIG. 3 is a diagram schematically illustrating a configuration of a subpixel according to an embodiment.

FIGS. 4A and 4B are diagrams illustrating structures of the first and second light control elements according to an embodiment.

FIG. 5 is a diagram illustrating a display apparatus for a vehicle, to which the display apparatus is applied, according to an embodiment.

FIG. 6 is an equivalent circuit diagram illustrating a configuration of a subpixel according to an embodiment.

FIG. 7 is a diagram illustrating a driving waveform of a subpixel according to an embodiment.

FIG. 8 is an enlarged plan view illustrating an area A structure in the display panel illustrated in FIG. 1 according to an embodiment.

FIG. 9 is a plan view illustrating a region A structure shown in FIG. 8 including a black matrix according to an embodiment.

FIG. 10 is an enlarged plan view illustrating a structure of a pixel area among areas A shown in FIG. 8 according to an embodiment.

FIG. 11 is a plan view illustrating a structure of a pixel region illustrated in FIG. 10 including a black matrix according to an embodiment.

FIG. 12 is a cross-sectional view illustrating a structure of a subpixel area taken along the line I-I′ in a pixel area illustrated in FIG. 11 according to an embodiment.

FIG. 13 is a cross-sectional view schematically illustrating a first light emitting region illustrated in FIG. 12 according to an embodiment.

FIG. 14 is a cross-sectional view illustrating a structure of a subpixel area taken along the line I-I′ in a pixel area illustrated in FIG. 11 according to an embodiment.

FIG. 15 is a cross-sectional view schematically illustrating a first light emitting region illustrated in FIG. 14 according to an embodiment.

FIG. 16 is a cross-sectional view illustrating a structure of a subpixel area taken along the line I-I′ in a pixel area illustrated in FIG. 11 according to an embodiment.

FIG. 17 is a cross-sectional view schematically illustrating a first light emitting region illustrated in FIG. 16 according to an embodiment.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically The embodiments of the present disclosure may be carried out independently from each other, or may be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region may be a source electrode, and a drain region may be a drain electrode. Also, a source region may be a drain electrode, and a drain region may be a source electrode.

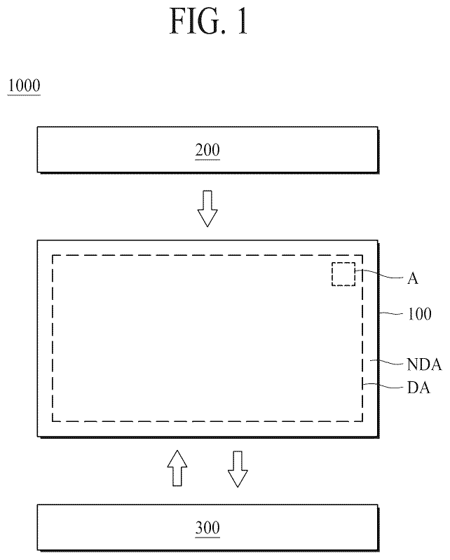

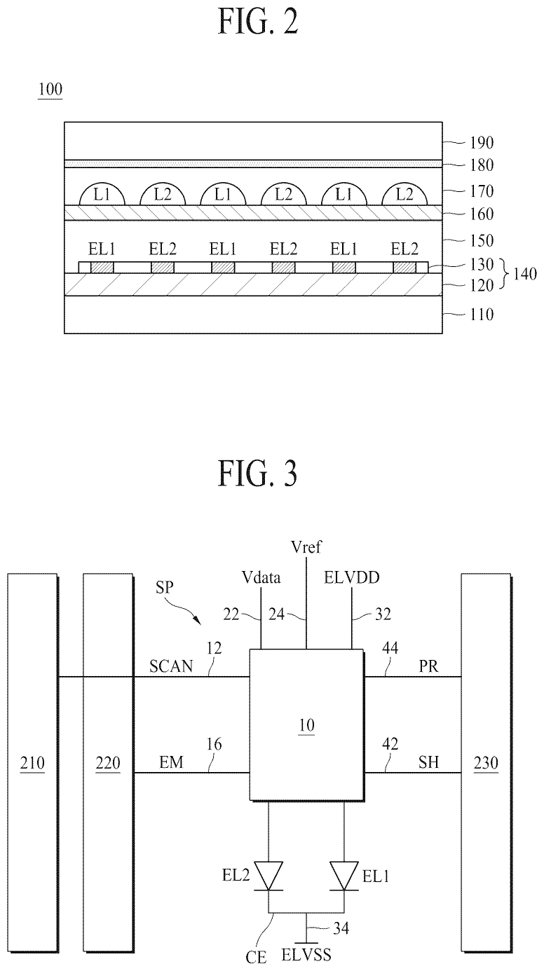

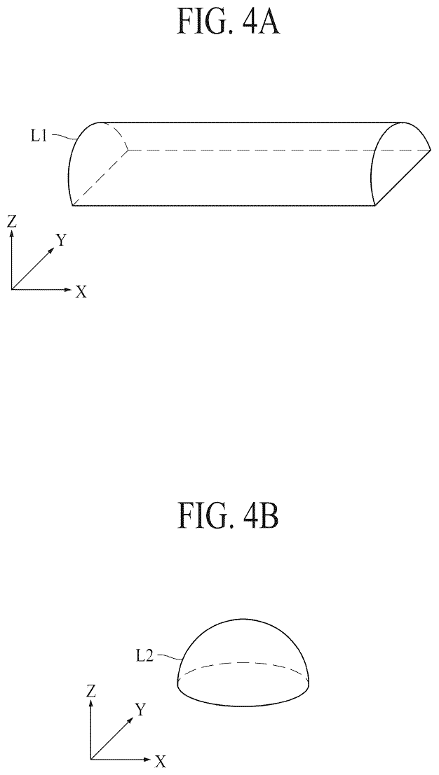

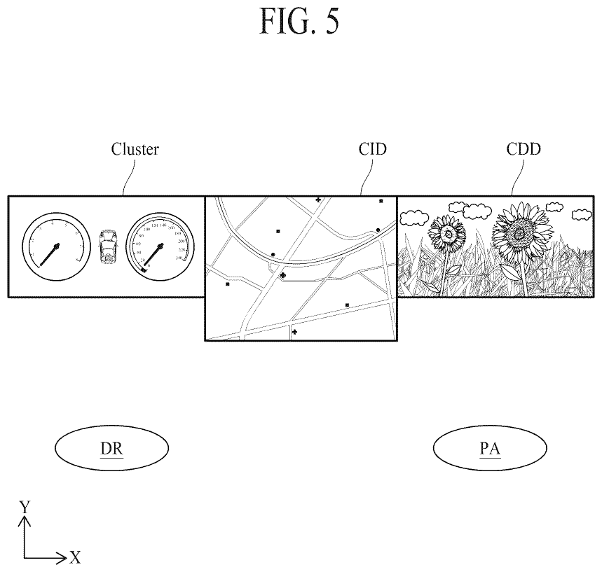

FIG. 1 is a diagram schematically illustrating a configuration of a display apparatus according to an embodiment, FIG. 2 is a cross-sectional view schematically illustrating a structure of a display panel according to an embodiment, FIG. 3 is a diagram schematically illustrating a configuration of a subpixel according to an embodiment, FIGS. 4A and 4B are diagrams illustrating structures of the first and second light control elements according to an embodiment, and FIG. 5 is a diagram illustrating a display apparatus for a vehicle to which the display apparatus according to an embodiment is applied.

The display apparatus 1000 according to an embodiment may provide both a display function for displaying an image and a touch sensing function for sensing the presence or absence of a user's touch and/or touch coordinates.

The display apparatus 1000 according to an embodiment may be an electroluminescent display apparatus including a touch sensor or a micro light emitting diode display apparatus. An electroluminescent display apparatus including a touch sensor may be an organic light emitting diode (OLED) display apparatus, a quantum-dot light emitting diode display apparatus, or an inorganic light emitting diode display apparatus.

Referring to FIG. 1, the display apparatus 1000 may include a display panel 100, a display driving circuit 200 for driving the display panel 100, and a touch sensing circuit 300 for driving and sensing a touch sensor array embedded into the display panel 100. The display apparatus 1000 may further include a power management circuit for generating and supplying a plurality of power voltages required for operations of the display panel 100, the display driving circuit 200, and the touch sensing circuit 300.

The display panel 100 may be a rigid display panel, or a flexible display panel capable of shape deformation such as a foldable, bendable, rollable, and stretchable display panel.

The display panel 100 may include a display area DA displaying an image and a non-display area NDA that is a bezel area surrounding the display area DA and positioned at the outer portion. The display panel 100 may further include a touch sensor array disposed in the display area DA to sense a user's touch.

The display panel 100 may display an image using the display area DA in which a plurality of subpixels is arranged in a matrix form. The pixel matrix of the display area DA may include a plurality of row lines consisting of a plurality of subpixels arranged in a first direction X and a plurality of column lines consisting of a plurality of subpixels arranged in a second direction Y. The display panel 100 may include a plurality of signal lines including a plurality of gate lines, a plurality of data lines, a plurality of power lines, and the like connected to a plurality of subpixels.

The plurality of subpixels may include a red subpixel emitting red light, a green subpixel emitting green light, and a blue subpixel emitting blue light. The plurality of subpixels may further include a white subpixel emitting white light. The unit pixel may include at least two subpixels.

The display driving circuit 200 may include a data driver that supplies a data signal to a plurality of data lines of the display panel 100, a gate driver that supplies a gate signal to a plurality of gate lines, and a timing controller that controls the operation of the data driver and the gate driver.

The touch sensing circuit 300 may include a touch driving circuit that supplies a touch driving signal to a touch sensor array embedded into the display panel 100, and receives a readout signal from the touch sensor array to generate sensing data, and a touch controller that detects the presence or absence of a touch and a touch coordinate position based on sensing data supplied from the touch driving circuit, and the like.

The touch sensor array may use a self-capacitance method that senses a change in self-capacitance according to a touch, or a mutual-capacitance method that senses a change in mutual-capacitance according to a touch.

The display panel 100 according to an embodiment may control a viewing angle according to a viewing angle mode. The display area DA of the display panel 100 may display an image in a first viewing angle mode in which a viewing angle with respect to the first direction is relatively wide or a second viewing angle mode in which a viewing angle with respect to the first direction is narrower than that of the first viewing angle mode. The first viewing angle mode may be expressed as a wide viewing angle mode or a shared mode. The second viewing angle mode may be expressed as a narrow viewing angle mode or a privacy mode. The display area DA of the display panel 100 may be driven in a switchable privacy mode (SPM) capable of switching the sharing mode and the privacy mode.

Referring to FIG. 2, the display panel 100 according to an embodiment may include a pixel array 140 including a circuit element layer 120 including a plurality of transistors and a plurality of signal lines disposed on the substrate 110, and a light emitting element layer 130 including a plurality of light emitting elements EL1 and EL2 disposed on the circuit element layer 120, and an encapsulation layer 150 disposed on the pixel array 140 to seal the light emitting element layer 130. The display panel 100 may include a touch sensor array 160 including a plurality of sensor electrodes disposed on the encapsulation layer 150, and a light control array 170 including a plurality of light control elements L1 and L2 disposed on the touch sensor array 160. The display panel 100 may further include a cover substrate 190 coupled to the light control array 170 by an optical clear adhesive (OCA) 180.

Referring to FIGS. 2 and 3, the subpixel SP according to an embodiment capable of controlling a viewing angle includes a first light emitting element EL1, a second light emitting element EL2, and a pixel circuit 10 for dividing and driving the first and second light emitting elements EL1 and EL2 according to a viewing angle mode, and a first light control element (L1 of FIG. 2) may be overlapped on the first light emitting element EL1, and a second light control element (L2 of FIG. 2) may be overlapped on the second light emitting element EL2.

The subpixel SP according to an embodiment may drive the first light emitting element EL1 in the first viewing angle mode and emit light having the first viewing angle through the first light control element L1. The subpixel SP may drive the second light emitting element EL2 in the second viewing angle mode and emit light having a second viewing angle narrower than the first viewing angle through the second light control element L2.

Referring to FIG. 4A, the first light control element L1 may have a half-cylindrical lens structure long in the first direction X, and the lens structure is not limited thereto. Referring to FIG. 4B, the second light control element L2 may have a half-spherical lens structure, and the lens structure is not limited thereto. In an embodiment, the first light control element L1 and the second light control element L2 may control (or limit) differently a viewing angle in the first direction X and control (or limit) equally a viewing angle in the second direction Y.

Depending on the embodiment, the light control elements L1 and L2 may be formed of a fluid material, a semi-fluid material, or a solid. The material and configuration of the light control elements L1 and L2 are not limited to the above-described examples. In addition, in some cases, the light control elements L1 and L2 may be referred to as a light control layer, a light control configuration, a lens, or a viewing angle control unit, but are not limited to these terms.

In FIGS. 4A and 4B, the first direction X may represent the left and right directions (e.g., horizontal directions) of the display panel 100, the second direction Y may represent the up and down direction (e.g., vertical direction) of the display panel 100, and the third direction Z may represent the front and rear directions (e.g., thickness direction) of the display panel 100.

In the first viewing angle mode, each subpixel SP of the display panel 100 drives the first light emitting element EL1 and does not limit the path of light emitted from the first light emitting element EL1 to within a specific angle in the first direction X, thereby providing light having a wide viewing angle.

In the second viewing angle mode, each subpixel SP of the display panel 100 may drive the second light emitting element EL2 and limit a path of light emitted from the second light emitting element EL2 through the second light control element L2 to within a specific cut-off angle in the first direction X to provide light having a narrow viewing angle.

The first light control element L1 and the second light control element L2 may control the path of light in the second direction Y to be within the cut-off angle to be controlled at a narrow viewing angle. Accordingly, when the display apparatus 1000 is applied to a vehicle as shown in FIG. 5, an image displayed on the display apparatus 1000 may be prevented from being reflected by the front glass of the vehicle to interfere with the driver's view.

The subpixel SP according to an embodiment may receive the data voltage Vdata from the data driver of the display driving circuit 200 through any one data line 22. The subpixel SP may receive the scan signal SCAN from the gate driver of the display driving circuit 200 through at least one gate line 12, and may receive the emission control signal EM through at least one gate line 16. The subpixel SP may receive the first mode signal SH from the gate driver of the display driving circuit 200 through any one gate line 42, and may receive the second mode signal PR through any one gate line 44. The subpixel SP according to an embodiment may receive the high-potential power voltage ELVDD from the power management circuit through the first power line 32, the low-potential power voltage ELVSS through the common electrode (cathode electrode) CE and the second power line 34, and may receive the reference voltage Vref through the reference line 24.

The gate driver may be embedded and disposed in the non-display area NDA of the display panel 100, and it is not limited thereto, the gate driver may be distributed and disposed in the display area DA. The gate driver according to an embodiment may be embedded in the display panel 100 in a gate in panel (GIP) type consisting of transistors formed in the same process as transistors of the display area DA.

The gate driver may include at least one scan driver 210 driving at least one gate line 12 and at least one emission control driver 220 driving at least one gate line 16. The number of gate lines connected to the subpixel SP, the number of scan drivers 210, and the number of emission control drivers 220 may be variously changed according to a detailed configuration of a pixel circuit constituting the subpixel SP.

The scan driver 210 may generate and supply at least one scan signal SCAN to at least one gate line 12 disposed in each of the plurality of pixel row lines.

The emission control driver 220 may generate and supply at least one emission control signal EM to at least one gate line 16 disposed in each of the plurality of pixel row lines.

In an embodiment, the gate driver may further include a mode control unit 230 for supplying mode signals SH and PR to the gate lines 42 and 44.

The mode control unit 230 may generate and supply a first mode signal SH through any one gate line 42 to each of a plurality of pixel row lines using a mode selection signal, and may generate and supply a second mode signal PR through any one of the gate lines 44. The mode control unit 230 may selectively drive the first light emitting element EL1 and the second light emitting element EL2 of each subpixel SP by using the first mode signal SH and the second mode signal PR.

In an embodiment, the first and second mode signals SH and PR may be supplied from the light emission control driver 220.

At least one of an LTPS transistor using a low temperature polysilicon (LTPS) semiconductor and an oxide transistor using a metal-oxide semiconductor may be applied to a plurality of transistors disposed in the display area DA of the display panel 100 and the non-display area NDA including the gate driver. The display panel 100 according to an embodiment may be configured such that an LTPS transistor and an oxide transistor coexist to reduce power consumption.

Referring to FIG. 5, a plurality of display apparatus disposed on a vehicle dashboard may include a cluster, a center information display CID, and a co-driver display CDD. A display apparatus that limits the viewing angle to within the cut-off angle in only the second direction Y for safe driving may be applied to the cluster and the central information display CID mainly used by the driver DR. A display apparatus including a touch sensor may be applied to the central information display CID. The display apparatus 1000 capable of controlling the viewing angle in the first viewing angle mode and the second viewing angle mode as in the above-described embodiment may be applied to the co-driver display CDD used by the driver DR and the passenger PA.

The co-driver display CDD may be driven in a first viewing angle mode under the control of the host system when the driver DR is not driving, and may provide an image having a wide viewing angle in the first direction X to the driver DR and the passenger PA.

When the driver DR drives, the co-driver display CDD may be driven in the second viewing angle mode under the control of the host system, may limit the viewing angle to within the cut-off angle in the first direction X to provide an image having a narrow viewing angle to only the passenger PA, and may not provide an image to the driver DR so as not to interfere with driving.

The display apparatus 1000 according to an embodiment may be applied not only to a co-driver display CDD, but also to various display apparatus such as a mobile display, an IT display, and a TV display that selectively requires viewing angle control for privacy and information protection.

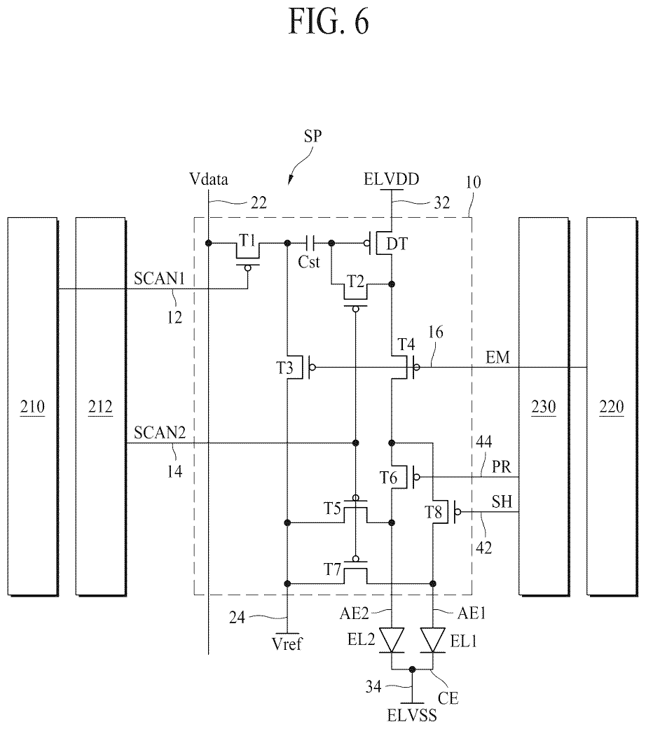

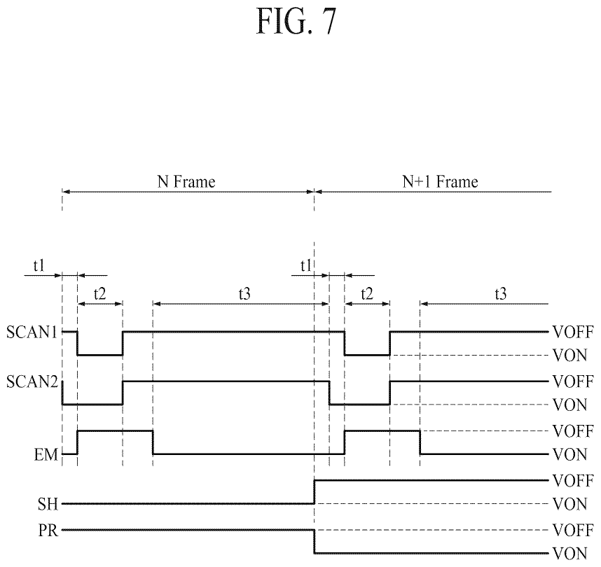

FIG. 6 is an equivalent circuit diagram illustrating a configuration of a subpixel according to an embodiment, and FIG. 7 is a diagram illustrating a driving waveform of a subpixel according to an embodiment.

Referring to FIG. 6, the subpixel SP may include first and second light emitting elements EL1 and EL2, and a pixel circuit 10 for separately driving the first and second light emitting elements EL1 and EL2. In an embodiment, the pixel circuit 10 may include a driving transistor DT, a plurality of switching transistors T1 to T8, and a storage capacitor Cst, but is not limited thereto.

The pixel circuit 10 may receive the first scan signal SCAN1 from the first scan driver 210 through the first gate line 12, and may receive the second scan signal SCAN2 from the second scan driver 212 through the second gate line 14. According to an embodiment, the first gate line 12 of FIG. 3 may include the first gate line 12 of FIG. 6.

The pixel circuit 10 may receive the emission control signal EM from the first emission control driver 220 through the third gate line 16.

In an embodiment, the pixel circuit 10 may receive the first mode signal SH from the mode control unit 230 through the fourth gate line 42, and may receive the second mode signal PR through the fifth gate line 44.

In an embodiment, the pixel circuit 10 may receive the first mode signal SH from the second light emission control driver 220 through the fourth gate line 42, and may receive the second mode signal PR through the fifth gate line 44.

The pixel circuit 10 may receive the data signal Vdata from the data driver through the data line 22. The pixel circuit 10 may receive the high potential power voltage ELVDD from the power management circuit through the first power line 32, the low potential power voltage ELVSS through the second power line 34 and the common electrode CE, and the reference voltage Vref through the reference line 24.

Referring to FIG. 7, the subpixel SP may be driven to include an initialization period t1, a sampling and writing period t2, and an emission period t3 for each frame period N and N+1. For convenience of description, in FIG. 7, the N frame period represents any one frame period of the first viewing angle mode, and the N+1 frame period represents any one frame period of the second viewing angle mode.

Each of the driving transistor DT and the plurality of switching transistors T1 to T8 of the pixel circuit 10 includes a gate electrode, a source electrode, and a drain electrode. Since the source electrode and the drain electrode are not fixed and may be changed according to the voltage and current direction applied to the gate electrode, one of the source electrode and the drain electrode may be expressed as the first electrode, and another one of the source electrode and the drain electrode may be expressed as the second electrode. The driving transistor DT and the plurality of switching transistors T1 to T8 of the pixel circuit 10 may use at least one of a polysilicon semiconductor, an amorphous silicon semiconductor, and an oxide semiconductor, and may use the P type or the N type and may be used in combination of the P type and the N type.

The first and second light emitting elements EL1 and EL2 may include the anode electrodes AE1 and AE2 individually connected to the eighth and sixth switching transistors T8 and T6, the cathode electrode CE receiving the low potential power voltage ELVSS from the second power line 34, and the light emitting layer disposed between the anode electrodes AE1 and AE2, and the cathode electrode CE. In the first and second light emitting elements EL1 and EL2, when driving current is supplied from the driving transistor DT through each of the eighth and sixth switching transistors T8 and T6, electrons from the cathode electrode CE are injected into the light emitting layer, and holes from the anode electrodes AE1 and AE2 are injected into the light emitting layer to emit light having a brightness proportional to the current value of the driving current by emitting fluorescent materials or phosphorescent materials by recombination of electrons and holes in the light emitting layer.

The gate electrode of the driving transistor DT may be connected to the storage capacitor Cst, the first electrode may be connected to the first power line 32 supplying the high potential power voltage ELVDD, and the second electrode may be connected to the first electrode of the fourth switching transistor T4. The driving transistor DT may be connected in common to the first electrodes of the sixth and eighth switching transistors T6 and T8 through the fourth switching transistor T4. The driving transistor DT may drive the first light emitting element EL1 through the fourth and eighth switching transistors T4 and T8, or may drive the second light emitting element EL2 through the fourth and sixth switching transistors T4 and T6. The driving transistor DT may control the light emission intensity of the first light emitting element EL1 through the fourth and eighth switching transistors T4 and T8 or may control the light emission intensity of the second light emitting element EL2 through the fourth and sixth switching transistors T4 and T6 by controlling the driving current according to the driving voltage charged in the storage capacitor Cst.

The storage capacitor Cst may be connected between the second electrode of the first switching transistor T1 and the gate electrode of the driving transistor DT to charge a driving voltage corresponding to the data voltage Vdata. The storage capacitor Cst may hold the charged driving voltage during the light emission period t3 during which the first switching transistor T1 is turned off, and supply the driving voltage to the driving transistor DT.

The first switching transistor T1 may be turned on or turned off in response to the first scan signal SCAN1 of the first gate line 12 disposed in the ith (i is a natural number) pixel row line. The first switching transistor T1 may supply the data voltage Vdata supplied through the data line 22 to the first electrode of the storage capacitor Cst during the sampling and writing period t2 in which the first scan signal SCAN1 has the gate-on voltage VON. The first switching transistor T1 may be turned off during the initialization period t1 and the light emission period t3 in which the first scan signal SCAN1 has the gate-off voltage VOFF.

The second, fifth, and seventh switching transistors T2, T5, and T7 may be turned on or off in response to the second scan signal SCAN2 supplied to the second gate line 14 of the i-th pixel row line. The second, fifth, and seventh switching transistors T2, T5, and T7 may be turned on during the initialization period t1 and the sampling and writing period t2 in which the second scan signal SCAN2 has the gate-on voltage VON, and may be turned off during the light emission period t3 in which the second scan signal SCAN2 has the gate-off voltage VOFF.

The second switching transistor T2 may connect the driving transistor DT in a diode structure by connecting the gate electrode of the driving transistor DT to the second electrode during the initialization period t1 and the sampling and writing period t2 in response to the second scan signal SCAN2. The second switching transistor T2 may charge the storage capacitor Cst by compensating the threshold voltage Vth of the driving transistor DT. Accordingly, the storage capacitor Cst may charge the data voltage compensated for the threshold voltage Vth of the driving transistor DT.

The fifth switching transistor T5 may supply the reference voltage Vref supplied through the reference line 24 to the anode electrode AE2 of the second light emitting element EL2 during the initialization period t1 and the sampling and writing period t2 in response to the second scan signal SCAN2.

The seventh switching transistor T7 may supply the initialization voltage Vref supplied through the reference line 24 to the anode electrode AE1 of the first light emitting element EL1 during the initialization period t1 and the sampling and writing period t2 in response to the second scan signal SCAN2.

The third and fourth switching transistors T3 and T4 may be turned on or turned off in response to the light emission control signal EM supplied to the third gate line 16 of the i-th pixel row line. The third and fourth switching transistors T3 and T4 may be turned on during the initialization period t1 and the light emission period t3 in which the light emission control signal EM has the gate-on voltage VON. The third and fourth switching transistors T3 and T4 may be turned off during the sampling and writing period t2 and a period between the sampling and writing period t2 and the light emission period t3 in which the light emission control signal EM has the gate-off voltage VOFF.

The third switching transistor T3 may supply the reference voltage Vref supplied through the reference line 24 to the first electrode of the storage capacitor Cst during the initialization period t1 and the light emission period t3 in response to the light emission control signal EM.

The fourth switching transistor T4 may connect the driving transistor DT to the sixth and eighth switching transistors T6 and T8 during the initialization period t1 and the light emission period t3 in response to the light emission control signal EM.

The eighth switching transistor T8 may be turned on or off in response to the first mode signal SH supplied to the fourth gate line 42 of the i-th pixel row line. The eighth switching transistor T8 may be turned on during the driving period N frame of the first viewing angle mode in which the first mode signal SH has the gate-on voltage VON, and may be turned off during the driving period N+1 frame of the second viewing angle mode in which the first mode signal SH has the gate-off voltage VOFF.

The eighth switching transistor T8 may connect the fourth switching transistor T4 to the first light emitting element EL1 during the driving period N frame of the first viewing angle mode in response to the first mode signal SH.

During the light emission period t3 of the driving period N frame of the first viewing angle mode, the driving transistor DT may drive the first light emitting element EL1 through the fourth and eighth switching transistors T4 and T8. Accordingly, the subpixel SP may provide light of the first viewing angle through the first light emitting element EL1 and the first light control element (see L1 of FIG. 4A).

The sixth switching transistor T6 may be turned on or off in response to the second mode signal PR supplied to the fifth gate line 44 disposed in the i-th pixel row line. The sixth switching transistor T6 may be turned on during the driving period N+1 frame of the second viewing angle mode in which the second mode signal PR has the gate-on voltage VON, and may be turned off during the driving period N frame of the first viewing angle mode in which the second mode signal PR has the gate-off voltage VOFF.

The sixth switching transistor T6 may connect the fourth switching transistor T4 to the second light emitting element EL2 during the driving period N+1 frame of the second viewing angle mode in response to the second mode signal PR.

During the light emission period t3 of the driving period N+1 frame of the second viewing angle mode, the driving transistor DT may drive the second light emitting element EL2 through the fourth and sixth switching transistors T4 and T6. Accordingly, the subpixel SP may provide light of the second viewing angle through the second light emitting element EL2 and the second light control element L2 (FIG. 4B).

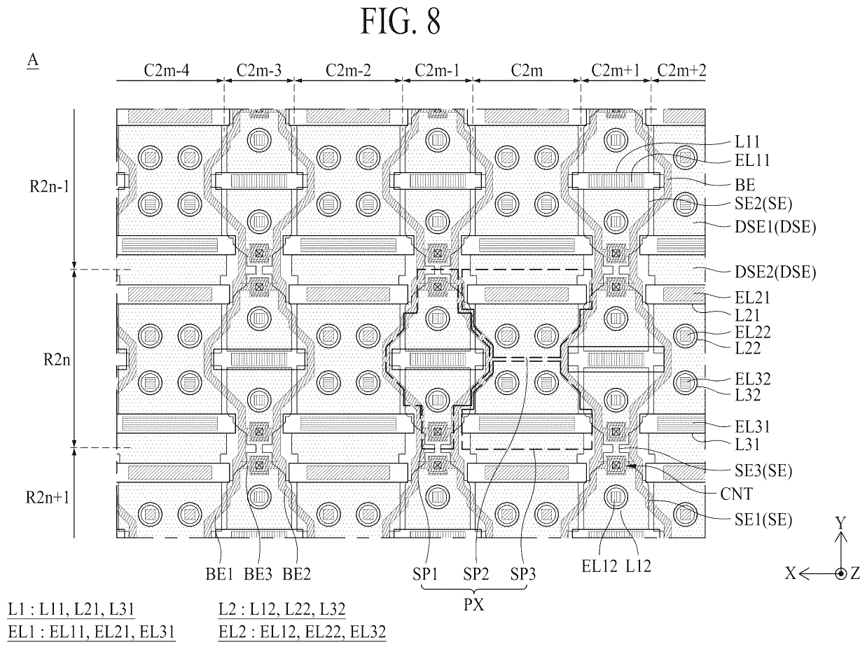

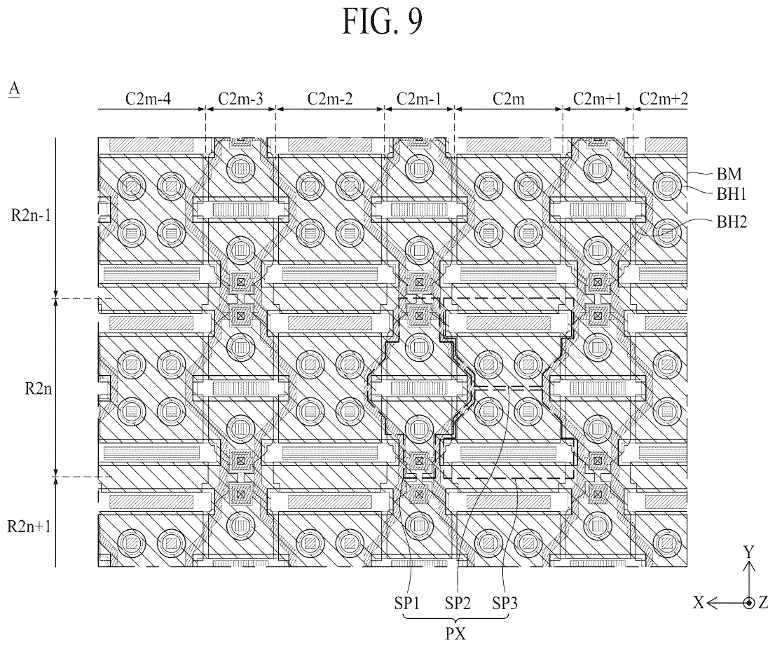

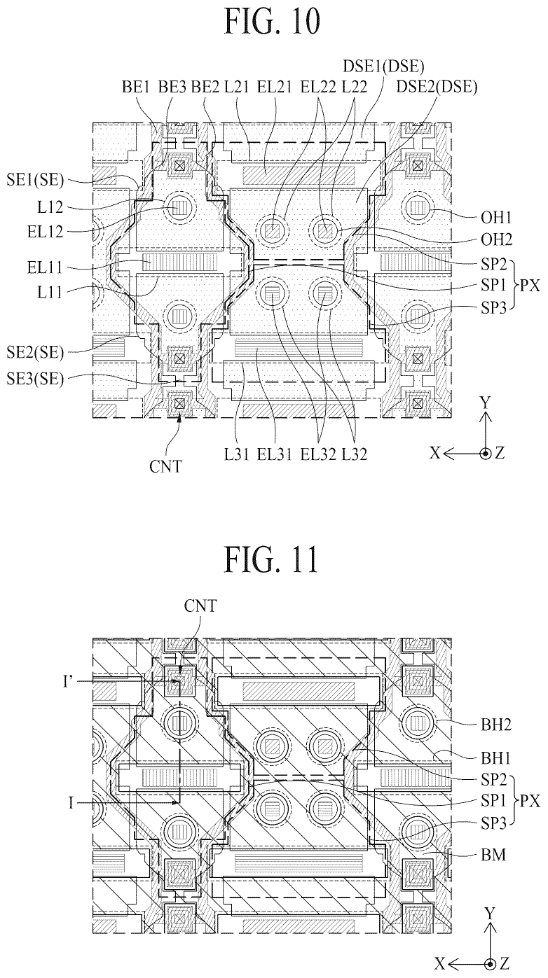

FIG. 8 is an enlarged plan view illustrating an area A structure in the display panel illustrated in FIG. 1 according to an embodiment, FIG. 9 is a plan view illustrating an area A structure shown in FIG. 8 including a black matrix according to an embodiment, FIG. 10 is an enlarged plan view illustrating a structure of a pixel area among areas A shown in FIG. 8 according to an embodiment, and FIG. 11 is a plan view illustrating a structure of a pixel area illustrated in FIG. 10 including a black matrix according to an embodiment.

Referring to FIGS. 8 to 11, area A is an enlarged view of a plurality of pixel areas on the display panel 100 according to an embodiment illustrated in FIG. 1. The area A of the display panel 100 according to an embodiment may have a structure in which a pixel array, a touch sensor array, and a light control array at least partially overlap. The pixel array may include a plurality of subpixels SP1, SP2, and SP3 having a plurality of light emitting elements EL1:EL11, EL21, EL31, and EL2:EL12, EL22, EL32. The touch sensor array may include a plurality of sensor electrodes SE, a bridge electrode BE, a dummy electrode DSE, and a black matrix BM. The light control array may include a plurality of light control elements L1:L11, L21, L31, and L2:L12, L22, L32.

The pixel array may include a 2n-1 row line R2n-1, (n is a natural number) and a 2n row line R2n including a plurality of subpixels SP1, SP2, and SP3 arranged in the first direction X, and a 2m-1 column line C2m-1, (m is a natural number) and a 2m column line C2m including a plurality of subpixels SP1, SP2, and SP3 arranged in the second direction Y.

The 2m-1 column line C2m-1 may include a plurality of first type subpixels SP1 arranged in the second direction Y. The 2m column line C2m may include a plurality of second and third type subpixels SP2 and SP3 alternately arranged in the second direction Y.

Each of the 2n-1 row line R2n-1 and the 2n row line R2n may include a plurality of first to third type subpixels SP1, SP2, and SP3 in which the first type subpixels SP1 and the second to third type subpixels SP2 and SP3 are alternately disposed in the first direction X.

Referring to FIGS. 8 to 11, each pixel PX may include a first type subpixel SP1 emitting first color light, a second type subpixel SP2 emitting second color light, and a third type subpixel SP3 emitting third color light. The first type subpixel SP1 may be disposed adjacent to the second and third type subpixels SP2 and SP3 in the first direction X. The second and third type subpixels SP2 and SP3 may be disposed adjacent and parallel to each other in the second direction Y.

The first type subpixel SP1 may include a first light emitting element EL11, a first light control element L11 overlapping on the first light emitting element EL11, at least one second light emitting element EL12, and at least one second light control element L12 overlapping on the at least one second light emitting element EL12. In an embodiment, in the first type subpixel SP1, two second light emitting elements EL12 may be disposed to be separated from each other with the first light emitting element EL11 interposed therebetween in the second direction Y. The two second light emitting elements EL12 may have a parallel connection structure in which anode electrodes are connected to each other. A plurality of the second light emitting element EL12 may emit light at a same time, and the first light emitting element EL11 may not emit light when the plurality of the second light emitting element EL12 emit the light at the same time.

In the first type subpixel SP1, two second light control elements L12 may be disposed to be separated from each other with the first light control element L11 interposed therebetween in the second direction Y. The second light emitting element EL12 and the second light control element L12 of the first type subpixel SP1 may be disposed adjacent to the second light emitting element EL12 and the second light control element L12 of another first type subpixel SP1 adjacent to each other in the second direction Y.

The first type subpixel SP1 may be a red subpixel having first and second light emitting elements EL11 and EL12 that emit red light.

The second type subpixel SP2 may include a first light emitting element EL21, a first light control element L21 overlapped on the first light emitting element EL21, at least one second light emitting element EL22, and at least one second light control element L22 overlapped on the at least one second light emitting element EL22.

In the second type subpixel SP2, two second light emitting elements EL22 may be disposed in parallel in the first direction X, and the first light emitting element EL21 and the two second light emitting elements EL22 may be separated from each other in the second direction Y. The two second light emitting elements EL22 may have a parallel connection structure in which anode electrodes are connected to each other.

In the second type subpixel SP2, two second light control elements L22 may be disposed in parallel in the first direction X, and the first light control element L21 and the two first light control elements L22 may be disposed separately in the second direction Y.

The second type subpixel SP2 may be a green subpixel having first and second light emitting elements EL21 and EL22 that emit green light.

In the third type subpixel SP3, two second light emitting elements EL32 may be disposed in parallel in the first direction X, and the first light emitting element EL31 and the two second light emitting elements EL32 may be separated from each other in the second direction Y. The two second light emitting elements EL32 may have a parallel connection structure in which anode electrodes are connected to each other.

In the third type subpixel SP3, two second light control elements L32 may be disposed in parallel in the first direction X, and the first light control element L31 and the two second light control elements L32 may be disposed separately in the second direction Y.

The second light emitting element EL22 and the second light control element L22 of the second type subpixel SP2 may be disposed adjacent to the second light emitting element EL32 and the second light control element L32 of the third type subpixel SP3 of the same pixel PX adjacent to each other in the second direction Y. The first light emitting element EL31 and the first light control element L31 of the third type subpixel SP3 may be disposed adjacent to the first light emitting element EL21 and the first light control element L21 of the second type subpixel SP2 of another pixel PX adjacent to each other in the second direction Y.

The third type subpixel SP3 may be a blue subpixel having first and second light emitting elements EL31 and EL32 that emit blue light.

The size of the first light emitting elements EL1: EL11, EL21, and EL31 may be larger than the size of the second light emitting elements EL2: EL12, EL22, and EL32. The size of the lower surfaces of the first light control elements L1: L11, L21, and L31 may be set larger than the size (the size of the light emitting area) of the first light emitting elements EL1: EL11, EL21, and EL31, so that the light emitting efficiency may be improved. The size of the lower surfaces of the second light control elements L2: L12, L22, and L32 may be set larger than the size (the size of the light emitting area) of the second light emitting elements EL2: EL12, EL22, and EL32, so that the light emitting efficiency may be improved.

In an embodiment, the sizes of the first light emitting elements EL11, EL21, and EL31 may be different for each color to compensate for a deviation in light emission efficiency for each color of the first light emitting elements EL11, EL21, and EL31. In an embodiment, the sizes of the first light emitting element EL11 and the first light control element L11 of the first type subpixel SP1 may be the smallest, and the sizes of the first light emitting element EL21 and the first light control element L21 of the second type subpixel SP2 may be equal to or smaller than the sizes of the first light emitting element EL31 and the first light control element L31 of the third type subpixel SP3.

In an embodiment, the sizes of the second light emitting elements EL12, EL22, and EL32 may be different for each color, or the number of light emitting regions having the same size may be different for each color to compensate for a variation in light emission efficiency for each color of the second light emitting elements EL12, EL22, and EL32. In an embodiment, the sizes (number) of the second light emitting element EL12 and the second light control element L12 of the first type subpixel SP1 may be the smallest, and the sizes (number) of the second light emitting element EL22 and the second light control element L22 of the second type subpixel SP2 may be equal to or smaller than the sizes (number) of the second light emitting element EL32 and the second light control element L32 of the third type subpixel SP3.

The touch sensor array may include a plurality of sensor electrodes SE, a plurality of dummy electrodes DSE, and a plurality of bridge electrodes BE disposed to overlap the non-emission area of the pixel array. The plurality of sensor electrodes SE and the plurality of dummy electrodes DSE may be disposed on the same layer to be separated from each other. The bridge electrode BE may be disposed on a different layer to overlap the sensor electrode SE and the dummy electrode DSE, and may electrically connect the plurality of sensor electrodes SE through the contact part CNT.

In an embodiment, a plurality of sensor electrodes SE may be disposed in a non-emission area of the first type subpixel SP1 along the 2m-1 column line C2m-1. A plurality of sensor electrodes SE may be separated in the second direction Y with the first light emitting element EL11 of the first type subpixel SP1 interposed therebetween.

Each of the plurality of sensor electrodes SE may include a first sensor electrode portion SE1 disposed in the non-emission area around the second light emitting element EL12 of the first type subpixel SP1 and a second sensor electrode portion SE2 disposed in the non-emission area around the second light emitting element EL12 of another first type subpixel SP1 adjacent to each other in the second direction Y. Each of the plurality of sensor electrodes SE may further include a third sensor electrode portion SE3 connecting the first sensor electrode portion SE1 to the second sensor electrode portion SE2 in the second direction Y.

In each of the first sensor electrode portion SE1 and the second sensor electrode portion SE2, a first portion surrounding the second light emitting element EL12 may have a relatively large area, a second portion overlapping the contact part CNT may have a smaller area than the first portion, and the third sensor electrode portion SE3 may have the smallest area.

The first sensor electrode portion SE1 and the second sensor electrode portion SE2 may be connected to the third sensor electrode portion SE3, respectively, so that the first sensor electrode portion SE1, the second sensor electrode portion SE2, and the third sensor electrode portion SE3 may be integrally formed. In this case, the first sensor electrode portion SE1, the second sensor electrode portion SE2, and the third sensor electrode portion SE3 forming an integral body may be positioned in an area between the first type subpixel SP1 located on the 2nth row line R2n and the first type subpixel SP1 located on the 2n+1 row line R2n+1, for example. More specifically, the first sensor electrode portion SE1 overlaps the first type subpixel SP1 located on the 2n+1 row line R2n+1, the second sensor electrode portion SE2 overlaps the first type subpixel SP1 located on the 2n row line R2n, and the third sensor electrode portion SE3 may be integrally formed together with the first sensor electrode portion SE1 and the second sensor electrode portion SE2 by being positioned in an area between the first type subpixel SP1 located on the 2n+1 row line R2n+1 and the first type subpixel SP1 located on the 2nth row line R2n.

The first sensor electrode portion SE1 and the second sensor electrode portion SE2 may have structures symmetrical in the second direction Y with respect to the third sensor electrode portion SE3.

Each of the first sensor electrode portion SE1 and the second sensor electrode portion SE2 may be electrically connected to the bridge electrode BE through the contact part CNT adjacent to the third sensor electrode portion SE3 in the second direction Y. Two contact parts CNTs may be disposed in parallel in the second direction Y between the second light emitting elements EL12 of the first type subpixel SP1 adjacent to each other in the second direction Y, and the third sensor electrode portion SE3 may be disposed between the two contact parts CNT.

Each of the first sensor electrode portion SE1 and the second sensor electrode portion SE2 may include an opening part OH1 overlapping the light emitting area of the second light emitting element EL12 and overlapping the second light control element L12. The size of the opening part OH1 of each of the first and second sensor electrode portions SE1 and SE2 may be larger than the size of the light emitting area of the second light emitting element EL12 and smaller than the size of the lower surface of the second light control element L12. The first and second sensor electrode portions SE1 and SE2 may limit viewing angles of light emitted from the second light emitting element EL12 in the first and second directions X and Y and prevent light leakage.

The first sensor electrode portion SE1 and the second sensor electrode portion SE2 may have structures symmetrical in the second direction Y. The first sensor electrode portion SE1 and the second sensor electrode portion SE2 may be electrically connected to the bridge electrode BE through the contact part CNT.

The ends of the first sensor electrode portion SE1 and the second sensor electrode portion SE2 separated in the second direction Y with the first light emitting element EL11 of the first type sub pixel SP1 interposed therebetween overlap with a portion of the first light emitting element EL11 that is not overlapped with the first light control element L11, so that a viewing angle of light emitted from the first light emitting element EL11 in the second direction Y may be limited and light leakage may be prevented.

In an embodiment, each of a plurality of bridge electrodes BEs may pass through non-emission areas of the first to third type subpixels SP1, SP2, and SP3 and may be disposed along the second direction Y.

The bridge electrode BE may include first and second bridge electrode portions BE1 and BE2 extending in the second direction Y or along the 2m-1 column line C2m-1 and a third bridge electrode portion BE3 connecting the first bridge electrode portion BE1 to the second bridge electrode portions BE2. The first and second bridge electrode portions BE1 and BE2 may overlap the first sensor electrode SE around the second light emitting element EL12 of the first type subpixel SP1, and overlap the dummy electrode DSE around the second light emitting elements EL22 and EL32 of the second and third type subpixels SP2 and SP3.

The third bridge electrode portion BE3 may be electrically connected to the first sensor electrode portion SE1 and the second sensor electrode portion SE2 through the contact part CNT. Two contact parts CNTs may be disposed in parallel in the second direction Y between the second light emitting elements EL12 of the first type subpixel SP1, which are adjacent to each other in the second direction Y.

A plurality of dummy electrodes DSE may be disposed in the non-emission area of the 2m column line C2m. The plurality of dummy electrodes DSE may include a first dummy electrode DSE1 disposed in the non-emission area around the second light emitting elements EL22 and EL32 of the second and third type subpixels SP2 and SP3 adjacent to each other in the second direction Y, and a second dummy electrode DSE2 disposed in the non-emission area between the first light emitting elements EL21 and EL31 of the second and third type subpixels SP2 and SP3 adjacent to each other in the second direction Y. The first dummy electrode DSE1 may have an area larger than that of the second dummy electrode DSE2. The first and second dummy electrodes DSE1 and DSE2 may be floating electrodes that are not electrically connected to other electrodes. The floating first and second dummy electrodes DSE1 and DSE2 may reduce parasitic capacitance formed between the touch sensor array and the common cathode electrode of the pixel array, thereby reducing distortion of a touch driving signal and a touch sensing signal, thereby improving sensing performance.

The first dummy electrode DSE1 may include an open part OH2 overlapping the light emission area of the second light emitting elements EL22 and EL32, and overlapping the second light control elements L22 and L32. The size of the open part OH2 of the first dummy electrode DSE1 may be larger than the size of the light emission areas of the second light emitting elements EL22 and EL32 and smaller than the size of the lower surfaces of the second light control elements L22 and L32. The first dummy electrode DSE1 may limit viewing angles of light emitted from the second light emitting elements EL22 and EL32 in the first and second directions X and Y and prevent light leakage.

The ends of the first dummy electrode DSEL and the second dummy electrode DSE2 in the second direction Y overlap portions of the first light control elements L21 and L31 that do not overlap the first light emitting element EL21 and EL31, thereby limiting the viewing angle of light emitted from the first light emitting elements EL21 and EL31 in the second direction Y and preventing light leakage.

Referring to FIGS. 9 and 11, the touch sensor array may further include a black matrix BM disposed in a non-emitting area of the pixel array.

The black matrix BM may include a first opening BH1 overlapping the first light emitting elements EL1: EL11, EL21, and EL31, and a second opening BH2 overlapping the second light emitting elements EL2: EL12, EL22, and EL32. The size of the first opening BH1 of the black matrix BM may be greater than the size of the light emitting areas of the first light emitting elements EL1: EL11, EL21, and EL31. According to an embodiment, the size of the first opening BH1 of the black matrix BM may be greater than the size of the lower surfaces of the first light control elements L1: L11, L21, and L31. By forming in this way, leakage of the light from the first light emitting elements EL1: EL11, EL21, and EL31 may be prevented. Also, the size of the second opening BH2 of the black matrix BM may be greater than the size of the light emitting areas of the second light emitting elements EL2: EL12, EL22, and EL32. According to an embodiment, the size of the second opening BH2 of the black matrix BM may be greater than the size of the lower surfaces of the second light control elements L2: L12, L22, and L32. By forming in this way, light leakage of light emitted from the second light emitting elements EL2: EL12, EL22, and EL32 may be prevented. The black matrix BM may limit a viewing angle in the second direction Y of light emitted from the first light emitting elements EL1: EL11, EL21, and EL31, limit a viewing angle in the first and second directions X and Y of light emitted from the second light emitting elements EL2: EL12, EL22, and EL32, and prevent light leakage.

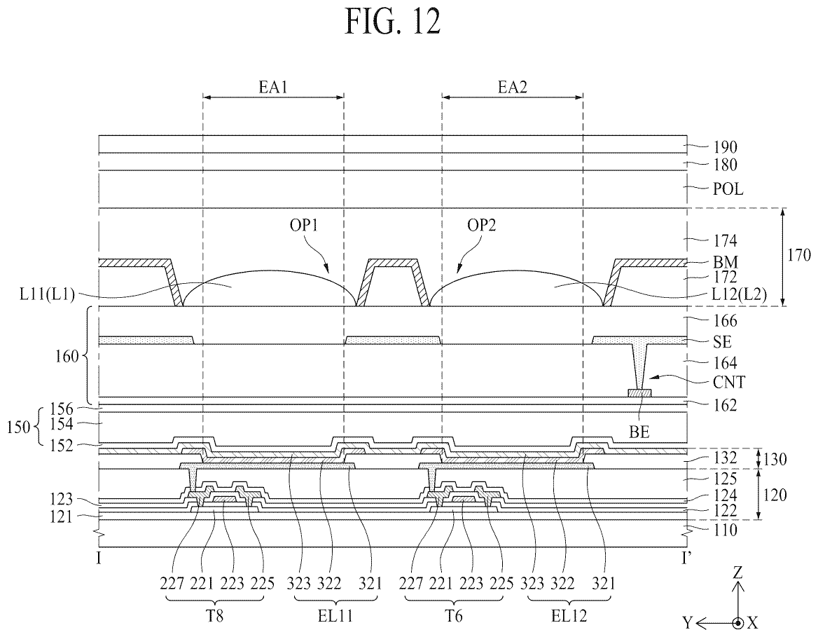

FIG. 12 is a cross-sectional view illustrating a structure of a subpixel area taken along a line I-I′ in a pixel area illustrated in FIG. 11 according to one embodiment.

FIG. 12 is a cross-sectional view illustrating a structure of a subpixel area along a cutting line I-I′ in a pixel area illustrated in FIG. 11 according to one embodiment.

Referring to FIG. 12, the display panel 100 according to an embodiment may include a pixel array 140 including a circuit element layer 120 disposed on the substrate 110 and a light emitting element layer 130 disposed on the circuit element layer 120, an encapsulation layer 150 disposed on the pixel array 140 to seal the light emitting element layer 130, a touch sensor array 160 disposed on the encapsulation layer 150, and a light control array 170 disposed on the touch sensor array 160. The display panel 100 may further include a polarizing plate POL disposed on the light control array 170, an optical transparent adhesive OCA 180, a cover substrate 190, and the like.

A cross-sectional structure of the first type subpixel SP1 among the first to third type subpixels SP1, SP2, and SP3 in the display panel 100 according to an embodiment will be described as an example with reference to FIG. 12. The first to third type subpixels SP1, SP2, and SP3 may have the same cross-sectional structure.

The first type subpixel SP1 may include the switching transistors T8 and T6 of the pixel circuit 10, the first light emitting element EL11 connected to the switching transistor T8, the second light emitting element EL12 connected to the switching transistor T6, the first light control elements L1: L11 overlapping the first light emitting area EA1 on the first light emitting element EL11, and the second light control elements L2: L12 overlapping the second light emitting area EA2 on the second light emitting element EL12.

The circuit element layer 120 according to an embodiment may include a plurality of insulating layers stacked on the substrate 110. For example, a plurality of insulating layers may include a buffer layer 121, a gate insulating layer 122, an interlayer insulating layer 123, a protective layer 124, and a planarization layer 125.

The substrate 110 may include an insulating material such as glass or plastic. The plastic substrate may be formed of a flexible material. For example, the substrate 110 may include at least one organic insulating material among an acrylic resin, an epoxy resin, a siloxane resin, a polyimide resin, and a polyamide resin.

The buffer layer 121 may have a single layer or multilayer structure including an inorganic insulating material such as silicon oxide (SiOx), silicon nitride (SiNₓ), aluminum oxide (Al₂O₃). The buffer layer 121 may prevent an impurity such as hydrogen from being introduced into the semiconductor layer 221 through the substrate 110.

A plurality of transistors including switching transistors T8 and T6 may be disposed on the buffer layer 121.

In an embodiment, the buffer layer 121 may include a multi-buffer layer and an active buffer layer. In this case, a multi-buffer layer may be disposed on the substrate 110 and an active buffer layer may be disposed on the multi-buffer layer. A light blocking layer may be disposed between the multi-buffer layer and the active buffer layer.

Each of the switching transistors T8 and T6 includes a semiconductor layer 221, a gate electrode 223, a source electrode 225 and a drain electrode 227 disposed on the buffer layer 121. The gate insulating layer 122 is disposed between the semiconductor layer 221 and the gate electrode 223. The interlayer insulating layer 123 is disposed between the gate electrode 223 and the source and drain electrodes 225 and 227. The source electrode 225 and the drain electrode 227 of each of the switching transistors T8 and T6 may be connected to the source region and the drain region of the semiconductor layer 221, respectively, through contact holes penetrating the interlayer insulating layer 123 and the gate insulating layer 122.

The semiconductor layer 221 may include polycrystalline silicon, or may include an oxide semiconductor material. The semiconductor layer 221 may include low-temperature polysilicon (LTPS). The semiconductor layer 221 may include at least one oxide semiconductor material among an IZO (InZnO)-based, an IGO (InGaO)-based, an ITO (InSnO)-based, an IGZO (InGaZnO)-based, an IGZTO (InGaZnSnO)-based, a GZTO (GaZnSnO)-based, a GZO (GaZnO)-based, and an ITZO (InSnZnO)-based. A light shielding layer (not shown) may be further disposed under the semiconductor layer 221.

The gate insulating layer 122 may include an inorganic insulating material such as silicon oxide (SiOx) and silicon nitride (SiNₓ). The gate insulating layer 122 may include a material having a high dielectric constant. For example, the gate insulating layer 122 may include a High-K material such as hafnium oxide (HfO). The gate insulating layer 122 may have a multilayer structure.

The gate electrode 223 and the gate line may be disposed on the gate insulating layer 122.

The interlayer insulating layer 123 may include an inorganic insulating material such as silicon oxide (SiOx) and silicon nitride (SiNₓ). The interlayer insulating layer 123 may have a multilayer structure.

A source electrode 225 and a drain electrode 227, a data line, and a power line may be disposed on the interlayer insulating layer 123.

The protection layer 124 and the planarization layer 125 may be stacked on the switching transistors T8 and T6. The protection layer 124 may include an inorganic insulating material such as silicon oxide (SiOx) and silicon nitride (SiNₓ). The planarization layer 125 may include an organic insulating material different from that of the protection layer 124 and may provide a flat surface. The planarization layer 125 may have a double layer structure.

A light emitting element layer 130 including light emitting elements EL11 and EL12 may be disposed on the planarization layer 125.

Each of the first and second light emitting elements EL11 and EL12 may include an anode electrode 321 disposed on the planarization layer 125, a light emitting layer 322 disposed on the anode electrode 321, and a common cathode electrode 323 disposed on the light emitting layer 322.

The anode electrode 321 of the first light emitting element EL11 may be connected to any one of the source electrode 225 and the drain electrode 227 of the switching transistor T8 through a contact hole penetrating the planarization layer 125 and the protective layer 124. The anode electrode 321 of the second light emitting element EL12 may be connected to any one of the source electrode 225 and the drain electrode 227 of the switching transistor T6 through a contact hole penetrating the planarization layer 125 and the protective layer 124.

The anode electrode 321 may include a conductive material having a high reflectivity. The anode electrode 321 may include a metal such as aluminum (Al), silver (Ag), titanium (Ti), and a silver-palladium-copper (APC) alloy. The anode electrode 321 may further include a transparent conductive material such as an indium tin oxide (ITO) or an indium zinc oxide (IZO). In an embodiment, the anode electrode 321 may have a multilayer structure (Ti/Al/Ti) of titanium (Ti) and aluminum (Al), a multilayer structure (ITO/AI/ITO) of ITO and aluminum (Al), or a multilayer structure (ITO/APC/ITO) of ITO and APC.

The light emitting layer 322 may include an emission material layer (EML) including a light emitting material. The light emitting material may include an organic material, an inorganic material, or a hybrid material. The light emitting layer 322 may have a multilayer structure. In an embodiment, the light emitting layer 322 may further include at least one of a hole injection layer (HIL), a hole transport layer (HTL), an electron transport layer (ETL), and an electron injection layer (EIL).

The cathode electrode 323 may be a common electrode and may include a conductive material that transmits light. The cathode electrode 323 may include a transparent conductive material such as ITO or IZO. The cathode electrode 323 may include aluminum (Al), magnesium (Mg), silver (Ag), or an alloy thereof and may have a thin thickness capable of transmitting light. Light generated by the light emitting layer 322 may be emitted through the cathode electrode 323.

The bank insulating layer 132 may be positioned on the anode electrode 321 of the first and second light emitting elements EL11 and EL12. The anode electrodes 321 of the first and second light emitting elements EL11 and EL12 are spaced apart from each other, and the bank insulating layer 132 may be positioned between the anode electrodes 321 of the first and second light emitting elements EL11 and EL12. The bank insulating layer 132 may cover the edge of the anode electrode 321. The bank insulating layer 132 may include an organic insulating material. The bank insulating layer 132 may include an organic material different from that of the planarization layer 125, and may have a single layer or a double layer structure.

The bank insulating layer 132 may include a plurality of open parts through which the anode electrodes 321 of the first and second light emitting elements EL11 and EL12 are exposed to define a plurality of light emission areas EA1 and EA2. For example, the bank insulating layer 132 may define a first light emitting area EA1 including an opening through which the anode electrode 321 of the first light emitting element EL11 is exposed, and may define a second light emitting area EA2 including an opening through which the anode electrode 321 of the second light emitting element EL12 is exposed. The light emitting layer 322 and the cathode electrode 323 of the first and second light emitting elements EL11 and EL12 may be stacked on the anode electrode 321 exposed by the open part of the bank insulating layer 132.

The encapsulation layer 150 may be positioned on the light emitting element layer 130 including the first and second light emitting elements EL11 and EL12. The encapsulation layer 150 may prevent damage to the light emitting elements EL11 and EL12 due to external moisture and impact. The encapsulation layer 150 may have a multilayer structure. In an embodiment, the encapsulation layer 150 may include a first encapsulation layer 152, a second encapsulation layer 154, and a third encapsulation layer 156 that are sequentially stacked, but is not limited thereto. The first encapsulation layer 152, the second encapsulation layer 154, and the third encapsulation layer 156 may include an insulating material. The second encapsulation layer 154 may include a material different from that of the first encapsulation layer 152 and the third encapsulation layer 156. For example, the first encapsulation layer 152 and the third encapsulation layer 156 are inorganic encapsulation layers including an inorganic insulating material, and the second encapsulation layer 154 may include an organic encapsulation layer including an organic insulating material. Accordingly, the light emitting elements EL11 and EL12 of the display apparatus may be more effectively prevented from being damaged by external moisture and impact.

The touch sensor array 160 may include a first touch insulating layer 162 disposed on the encapsulation layer 150, a bridge electrode BE disposed on the first touch insulating layer 162, a second touch insulating layer 164 covering the bridge electrode BE, a sensor electrode SE and a dummy sensor electrode DSE disposed on the second touch insulating layer 164, and a third touch insulating layer 166 covering the sensor electrode SE and the dummy sensor electrode DSE. The bridge electrode BE, the sensor electrode SE, and the dummy sensor electrode DSE may be disposed in a non-emitting area overlapping the bank insulating layer 132. The bridge electrode BE may be connected to the sensor electrode SE through the contact part CNT to electrically connect the sensor electrode SE to another sensor electrode SE. For example, the bridge electrode BE may electrically connect the first sensor electrode (see SE1 of FIG. 10) to the second sensor electrode (see SE2 of FIG. 10).

A light control array 170 including a first light control element L11 and a second light control element L12 may be disposed on the touch sensor array 160.

A patterned first insulating layer 172 may be disposed on the touch sensor array 160. The first insulating layer 172 may include a plurality of openings OP1 and OP2. A plurality of openings OP1 and OP2 may include a first opening OP1 overlapping the first light emitting area EA1 and a second opening OP2 overlapping the second light emitting area EA2. A portion of the upper surface of the third touch insulating layer 166 of the touch sensor array 160 may be exposed by a plurality of openings OP1 and OP2. In this case, at least a portion of the third touch insulating layer 166 exposed by the first opening OP1 and the second opening OP2 may overlap the first light emitting element EL11 and the second light emitting element EL12, respectively.

The first insulating layer 172, for example, the first insulating layer 172 disposed between the first light control element L11 and the second light control element L12, includes a first side surface contacting the first opening OP1 and facing the first light control element L11 and a second side surface contacting the second opening OP2 and facing the second light control element L12, and an upper surface or top surface continuously connected between the first side surface and the second side surface.

According to an embodiment, the height of the first insulating layer 172 may be higher than the heights of the first light control element L11 and the second light control element L12. In this case, the height of each of the first insulating layer 172, the first light control element L11, and the second light control element L12 may be defined as the shortest distance from the upper surface of the touch sensor array 160, specifically from the upper surface of the third touch insulating layer 166, to the uppermost end of each of the first insulating layer 172, the first light control element L11, and the second light control element L12. The first light control element L11 may be disposed on an upper surface of the touch sensor array 160.

A black matrix BM may be disposed on the first insulating layer 172. The black matrix BM may be disposed to correspond to regions positioned between the first emitting area EA1 and the second emitting area EA2. The black matrix BM may be omitted from the first emitting area EA1 and the second emitting area EA2. In this case, the black matrix BM may not overlap the first emitting area EA1 and the second emitting area EA2 while continuously covering the entire surface of the first and second side surfaces and the top surface of the first insulating layer 172.

A portion of the black matrix BM, for example, a black matrix BM covering a side surface of the first insulating layer 172 may be partially disposed in the first opening OP1 and the second opening OP2 to be in contact with a portion of an upper surface of the third touch insulating layer 166 exposed by the first opening OP1 and the second opening OP2. In an embodiment, the black matrix BM may extend up to an upper surface of the touch sensor array 160, for example, an upper surface of the third touch insulating layer 166, and a lower end of the black matrix BM may be in contact with the first light control element L11 and the second light control element L12.

In an embodiment, the black matrix BM, for example, the black matrix BM positioned between the first light control element L11 and the second light control element L12, may include a first portion disposed on one side of the first insulating layer 172, for example, a left side, the first portion facing the first light control element L11, a second portion disposed on another side of the first insulating layer 172, for example, a right side, the second portion facing the second light control element L12, and a third portion continuously formed between the first portion and the second portion. The first insulating layer 172 may be disposed under the first portion, the second portion, and the third portion. Since the first to third portions of the black matrix BM are continuously formed, the first insulating layer 172 positioned between the first light control element L11 and the second light control element L12 may be covered by the black matrix BM.

According to an embodiment, since the black matrix BM is disposed on the side surface of the first insulating layer 172, light leakage from the first emitting area EA1 and the second emitting area EA2 may be prevented from occurring.

The first insulating layer 172 and the black matrix BM of the light control array 170 may be disposed in a non-emitting area overlapping the bank insulating layer 132. Therefore, the first insulating layer 172 and the black matrix BM may overlap the sensor electrode SE and the bridge electrode BE. According to an embodiment, the black matrix BM is formed to overlap on the bridge electrode BE, thereby preventing a problem that external light is reflected by the bridge electrode BE and improving visibility of the display panel (refer to 100 of FIG. 1).

The first light control element L11 and the second light control element L12 may be disposed on the touch sensor array 160. The first light control element L11 and the second light control element L12 may be disposed in a plurality of openings OP1 and OP2 in the same layer as the first insulating layer 172. Specifically, the first light control element L11 may be disposed in the first opening OP1, and the second light control element L12 may be disposed in the second opening OP2. In this case, a lower end or lower surface of the first light control element L11 in the first opening OP1 may be disposed on the same level as a lower end of the black matrix BM, and a lower end or lower surface of the second light control element L12 in the second opening OP2 may be disposed on the same level as a lower end of the black matrix BM. A lower surface of the first insulating layer 172 and a lower surface of the first light control element L11 may be disposed at a same height.

As the first light control element L11 is disposed in the first opening OP1, the first light control element L11 may be surrounded by the first insulating layer 172 and the black matrix BM. As the second light control element L12 is disposed in the second opening OP2, the second light control element L12 may be surrounded by the first insulating layer 172 and the black matrix BM.

In this case, even if the light emitted from the first light emitting area EA1 is refracted while passing through the first light control element L11, the light refracted more than necessary may be cut-off by the black matrix BM disposed around the first light control element L11. Even if the light emitted from the second light emitting area EA2 is refracted while passing through the second light control element L12, the light refracted more than necessary may be cut-off by the black matrix BM disposed around the second light control element L12.

The first light control element L11 overlaps the light emitting area EA1 of the first light emitting element EL11, and the second light control element L12 overlaps the light emitting area EA2 of the second light emitting element EL12. The first light control element L11 and the second light control element L12 may be disposed in the light emitting area EA1 of the first light emitting element EL11 and the light emitting area EA2 of the second light emitting element EL12 to control a path of light generated in the light emitting areas EA1 and EA2, respectively.

The first light control element L11 may control the traveling path of light generated in the light emitting area EA1 of the first light emitting element EL11 to be a wide viewing angle in the first direction X and to be a narrow viewing angle in the second direction Y, and may control the traveling path of light generated in the light emitting area EA2 of the second light emitting element EL12 to be a narrow viewing angle in the first and second directions X and Y.

The protective layer 174 may be positioned on the first light control element L11 and the second light control element L12. The protective layer 174 may include an organic insulating material. The refractive index of the protective layer 174 may be less than the refractive index of the first light control element L11 and the refractive index of the second light control element L12. Thus, the light passing through the first light control element L11 and the second light control element L12 may not be reflected toward the substrate 110 due to the difference in refractive index from the protective layer 174.

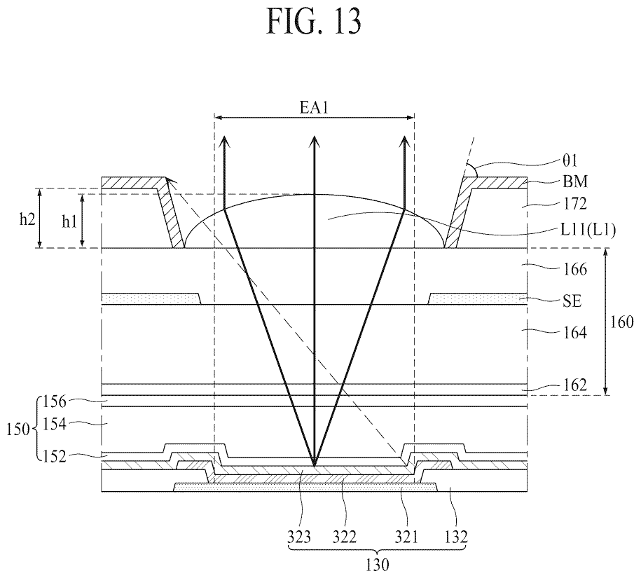

FIG. 13 is a cross-sectional view schematically illustrating a pixel region illustrated in FIG. 12 according to one embodiment. In this case, FIG. 13 schematically illustrates a first light emitting region of FIG. 12. Meanwhile, in FIG. 13, the same reference numerals are assigned to the elements overlapping with FIG. 12, and repeated descriptions thereof will be omitted.

Referring to FIG. 13, when light (a portion indicated by a solid line) emitted from the first light emitting area EA1 passes through the encapsulation layer 150, the touch sensor array 160, and the first light control element L11, even if the light emitted from the first light emitting area EA1 emits at a certain angle, the light directed to the side by the first light control element L11 faces the front. By forming in this way, it is possible to control the viewing angle in the first light emitting area EA1 and prevent or at least reduce light leakage.

Light emitted from the first light emitting area EA1 (a portion indicated by a dotted line) is cut-off by the black matrix BM disposed around the first light control element L11. Since light directed to the side surface of the first light emitting area EA1 is cut-off by the black matrix BM, light leakage can be prevented or at least reduced. The black matrix BM may be formed on the first insulating layer 172 to form a predetermined angle, and in this case, the angle between the black matrix BM disposed on the side surface of the first insulating layer 172 and the upper surface of the third touch insulating layer 166 may be the first angle θ1. According to an example, the first angle θ1 of the black matrix BM is, for example, an acute angle, so that the black matrix BM may have a tapered shape.

According to an embodiment, since the second height h2 of the first insulating layer 172 is formed to be greater than the first height h1 of the first light control element L11, the area of the black matrix BM formed on the side surface of the first insulating layer 172 is increased, and thus the rate at which light emitted from the first light emitting area EA1 (a portion indicated by a dotted line) is cut-off is increased, so that light leakage in the first light emitting area EA1 may be better prevented.

Meanwhile, although FIG. 13 exemplarily illustrates that light leakage is prevented in the first light emitting area EA1 of the first light emitting element EL11, the present disclosure is not limited thereto, the same may be applied to all of a plurality of light emitting elements EL11, EL12, EL21, EL22, EL31, and EL32.

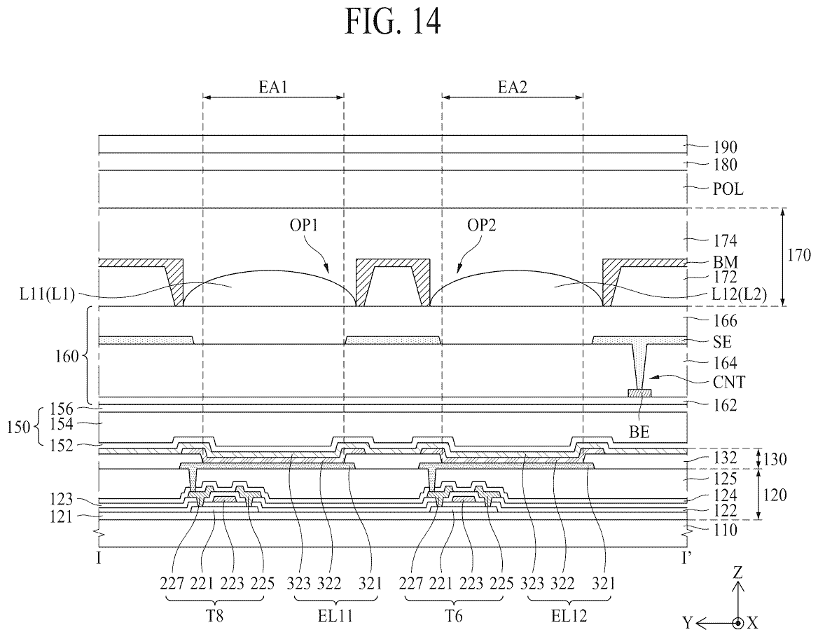

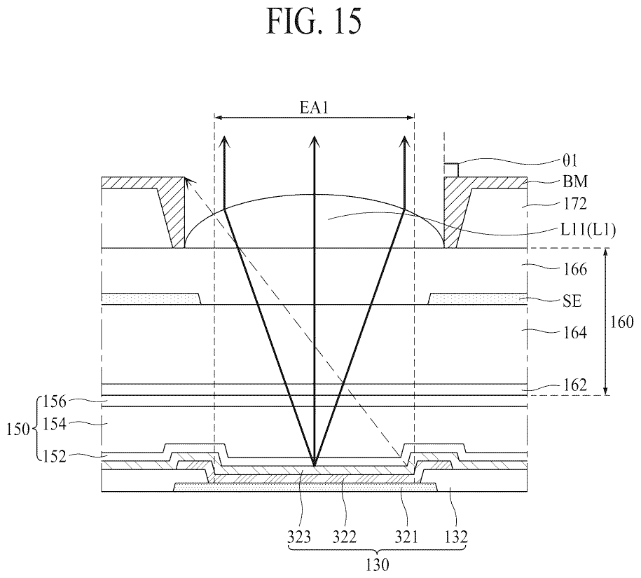

FIG. 14 is a cross-sectional view illustrating a structure of a subpixel region along the line I-I′ in a pixel region illustrated in FIG. 11 according to one embodiment, and FIG. 15 is a cross-sectional view schematically illustrating a first light emitting region illustrated in FIG. 14 according to one embodiment. Meanwhile, an embodiment of FIGS. 14 and 15 is the same as an embodiment of FIGS. 12 and 13 except for a configuration of a black matrix, and thus different configurations will be mainly described below.

Referring to FIG. 14, the display panel 100 according to another embodiment may include a circuit element layer 120 disposed on the substrate 110 and a pixel array 140 including the light emitting element layer 130 disposed on the circuit element layer 120, an encapsulation layer 150 disposed on the pixel array 140 to seal the light emitting element layer 130, a touch sensor array 160 disposed on the encapsulation layer 150, and a light control array 170 disposed on the touch sensor array 160. The display panel 100 may further include a polarizing plate POL disposed on the light control array 170, an optical clear adhesive (OCA) 180, a cover substrate 190, and the like.

The black matrix BM of the display panel 100 according to another embodiment may include, for example, a side surface perpendicular to the upper surface of the third touch insulating layer 166. By forming in this way, an angle formed by the side surface of the black matrix BM with the third touch insulating layer 166 and an angle formed by the side surface of the first insulating layer 172 with the third touch insulating layer 166 may be different from each other. In this case, the thickness of the black matrix BM may increase from the lower end of the black matrix BM in contact with the side surface of the first insulating layer 172, for example, from a portion of the black matrix BM in contact with the third touch insulating layer 166 toward the third direction Z. In this case, the thickness of the black matrix BM may be defined as the shortest distance from the side surface of the first insulating layer 172 in the second direction Y of the black matrix BM. A thickness of a portion of the black matrix BM disposed on an upper end of a first side surface of the first insulating layer 172 may be thicker than a thickness of a portion of the black matrix BM disposed on a lower end of the first side surface of the first insulating layer 172.

Referring to FIG. 15, an angle formed between the side surface of the black matrix BM and the top surface of the black matrix BM or an angle formed by the black matrix BM contacting the side surface of the first insulating layer 172 with the top surface of the third touch insulating layer 166 may be a first angle θ1. According to an embodiment, the first angle θ1 may be 90°.

Since the side surface of the black matrix BM is formed at a right angle, light emitted from the first light emitting area EA1 and the second light emitting area EA2 may be cut-off at an angle of a predetermined angle or more, and light leakage may be better prevented.

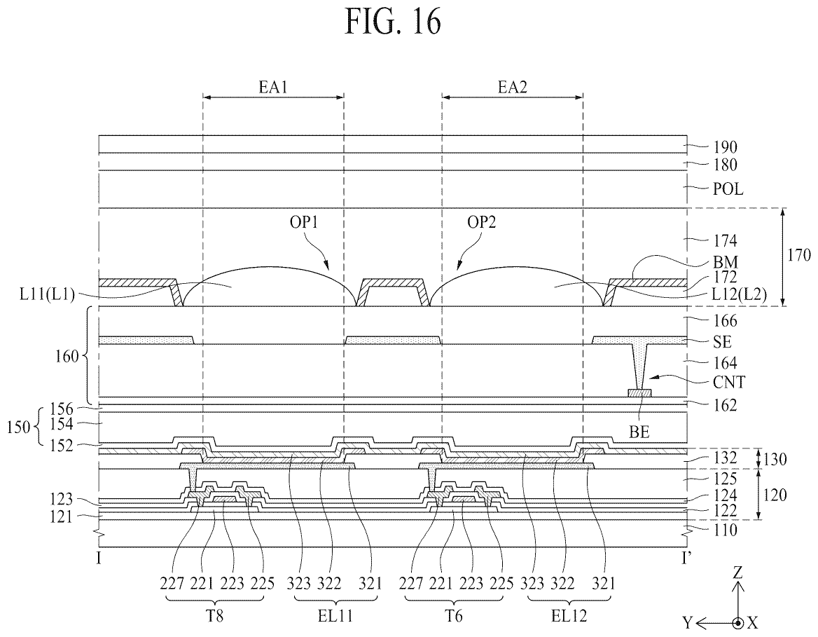

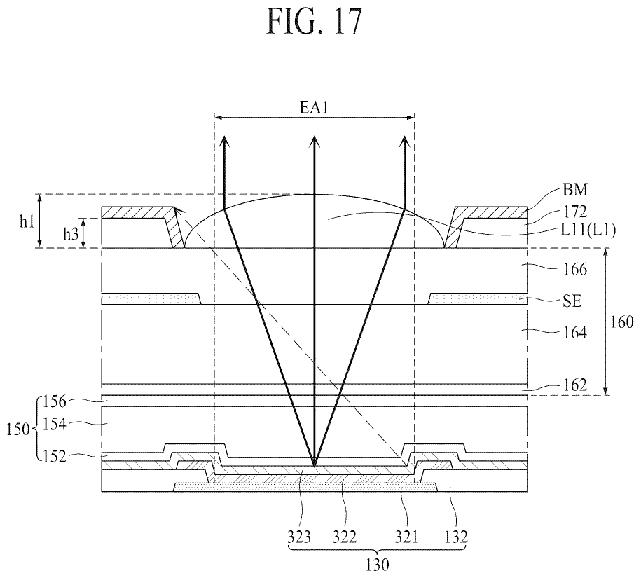

FIG. 16 is a cross-sectional view illustrating a structure of a subpixel region along the line I-I′ in a pixel region illustrated in FIG. 11 according to one embodiment, and FIG. 17 is a cross-sectional view schematically illustrating a first light emitting region illustrated in FIG according to one embodiment. 16. Meanwhile, an embodiment of FIGS. 16 and 17 is the same as an embodiment of FIGS. 12 and 13, except for a first insulating layer and a black matrix, and thus different configurations will be mainly described below.

Referring to FIG. 16, the display panel 100 according to another embodiment may include a circuit element layer 120 disposed on the substrate 110 and a pixel array 140 including the light emitting element layer 130 disposed on the circuit element layer 120, an encapsulation layer 150 disposed on the pixel array 140 to seal the light emitting element layer 130, a touch sensor array 160 disposed on the encapsulation layer 150, and a light control array 170 disposed on the touch sensor array 160. The display panel 100 may further include a polarizing plate POL disposed on the light control array 170, an optical clear adhesive (OCA) 180, a cover substrate 190, and the like.

The first insulating layer 172 of the display panel 100 according to another embodiment may be formed at a height lower than that of the first light control element L11 and/or the second light control element L12. Thus, a height of an upper surface of the first insulating layer 172 from the third touch insulating layer 166 may be lower than a height of an upper end of the first light control element L11 or the second light control element L12.

Referring to FIG. 17, the first light control element L11 may have a first height h1, and the first insulating layer 172 may have a third height h3. Even in this case, the light leakage phenomenon is prevented by the black matrix BM formed on the first insulating layer 172. Specifically, even if the light emitted from the first light emitting area EA1 has an inclination of a predetermined angle or more, the light is cut off by the black matrix BM to prevent light leakage.

According to an embodiment, at least a portion of the light control elements L11 and L12 may overlap the black matrix BM. For example, at least a portion of both ends of the light control elements L11 and L12 may overlap the black matrix BM. In this case, the light leakage space, which may be provided due to a process error or the like, is eliminated between the light control elements L11 and L12 and the black matrix BM, so that light leakage may be more effectively prevented.

Accordingly, the present disclosure may have the following advantages.

According to an embodiment of the present disclosure, since a light control element is disposed in an opening of the first insulating layer formed on the touch sensor array and a black matrix covering the upper and side surfaces of the first insulating layer is formed, light emitted from the light emitting area may be refracted by the light control element to a certain angle or more to prevent or at least reduce light leakage.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A display apparatus comprising:
a substrate including a first emitting area and a second emitting area;
a first insulating layer on the substrate, the first insulating layer including a first opening corresponding to the first emitting area and a second opening corresponding to the second emitting area;
a first light control element in the first opening;
a second light control element in the second opening; and
a black matrix on the first insulating layer in a region between the first emitting area and the second emitting area,
wherein the first insulating layer includes a first side surface in contact with the first opening and an upper surface connected to the first side surface, and the black matrix is on the first side surface and the upper surface of the first insulating layer.

2. The display apparatus according to claim 1, wherein the first insulating layer further includes a second side surface that is in contact with the second opening, and the black matrix is further disposed on the second side surface of the first insulating layer.

3. The display apparatus according to claim 2, wherein the black matrix is continuous on an entire surface of the first side surface, the second side surface, and the upper surface of the first insulating layer.

4. The display apparatus according to claim 1, wherein a lower surface of the first insulating layer and a lower surface of the first light control element are disposed at a same height.

5. The display apparatus according to claim 1, wherein a lower end of the black matrix and a lower surface of the first light control element are disposed at a same height.

6. The display apparatus according to claim 1, wherein a touch sensor array is under the first insulating layer, and the first light control element is on an upper surface of the touch sensor array.

7. The display apparatus according to claim 6, wherein the black matrix extends up to an upper surface of the touch sensor array.

8. The display apparatus according to claim 6, wherein the touch sensor array includes a sensor electrode and a second insulating layer on the sensor electrode,
wherein the first light control element is on an upper surface of the second insulating layer, and the sensor electrode overlaps the black matrix.

9. The display apparatus according to claim 8, wherein the touch sensor array further includes a bridge electrode that is connected to the sensor electrode through a contact part, and the bridge electrode overlaps the black matrix.

10. The display apparatus according to claim 1, wherein the black matrix is in contact with the first light control element.

11. The display apparatus according to claim 1, wherein a height of an upper end of the first insulating layer is higher than a height of an upper end of the first light control element.

12. The display apparatus according to claim 1, wherein a height of an upper end of the first insulating layer is lower than a height of an upper end of the first light control element.

13. The display apparatus according to claim 1, wherein a thickness of a portion of the black matrix that is on an upper end of a first side surface of the first insulating layer is thicker than a thickness of a portion of the black matrix that is on a lower end of the first side surface of the first insulating layer.

14. The display apparatus according to claim 8, wherein the black matrix is partially disposed in the first opening and the second opening to be in contact with a portion of an upper surface of the second insulating layer that is exposed by the first opening and the second opening.

15. The display apparatus according to claim 8, wherein the black matrix extends to an upper surface of the second insulating layer, and a lower end of the black matrix is in contact with the first light control element and the second light control element.

16. The display apparatus according to claim 8, wherein the black matrix includes a side surface that is perpendicular to an upper surface of the second insulating layer.

17. A display apparatus comprising:
a plurality of light emitting elements including a first light emitting element and a second light emitting element;
a first light control element in the first light emitting element;
a second light control element in the second light emitting element; and
a black matrix between the first light emitting element and the second light emitting element,
wherein the black matrix is between the first light control element and the second light control element, and the black matrix includes a first portion facing the first light control element and a second portion facing the second light control element.

18. The display apparatus according to claim 17, wherein the black matrix further includes a third portion between the first portion and the second portion, and the third portion is connected to the first portion and the second portion, and a first insulating layer is under the first portion, the second portion, and the third portion.

19. The display apparatus according to claim 17, wherein a size of the first light emitting element is larger than a size of the second light emitting element.

20. The display apparatus according to claim 19, wherein the first light emitting element and the second light emitting element emit light of a same color, and the second light emitting element includes a plurality of second light emitting elements that face the first light emitting element.

21. The display apparatus according to claim 20, wherein the plurality of second light emitting elements emit light at a same time, and the first light emitting element does not emit light while the plurality of second light emitting elements emit the light at the same time.

22. The display apparatus according to claim 20, wherein the first light emitting element includes a first light emitting area including an anode, an organic light emitting layer, and a cathode,
the second light emitting element includes a second light emitting area including an anode, an organic light emitting layer, and a cathode,
wherein the anode of the first light emitting area is connected to a first switching transistor and the anode of the second light emitting area is connected to a second switching transistor,
and the first switching transistor and the second switching transistor are connected to a same driving transistor and the first light emitting area and the second light emitting area emit light of a same color.

23. The display apparatus according to claim 17, wherein the first light control element has a semi-cylindrical shape, and the first light emitting element is driven in a wide viewing angle mode, and the second light control element has a hemispherical shape and the second light emitting element is driven in a narrow viewing angle mode that has a viewing angle that is less than a viewing angle of the wide viewing angle mode.

24. The display apparatus according to claim 17, wherein the black matrix includes a first opening that overlaps the first light emitting element and a second opening that overlaps the second light emitting element,
wherein a size of the first opening of the black matrix is greater than a size of a light emitting area of the first light emitting element, and a size of the second opening of the black matrix is greater than a size of a light emitting area of the second light emitting element.

25. The display apparatus according to claim 18, wherein the black matrix is on a side surface of the first insulating layer.

26. The display apparatus according to claim 18, wherein a height of the first insulating layer is greater than a height of the first light control element.

27. The display apparatus according to claim 18, wherein the first insulating layer is at a height that is lower than a height of the first light control element or a height of the second light control element.

28. The display apparatus according to claim 18, wherein the black matrix continuously covers side surfaces and a top surface of the first insulating layer.

29. The display apparatus according to claim 17, wherein a size of a lower surface of the first light control element is larger than a size of the first light emitting element, and a size of a lower surface of the second light control element is larger than a size of the second light emitting element.
